(19) United States
(12) Patent Application Publication
(10) Pub. No.: US 2026/0206377 A1
(43) Pub. Date: Jul. 16, 2026

(54) LIGHT-EMITTING DEVICE

(71) Applicant: Bridgelux Optoelectronics (Xiamen) Co., Ltd., Xiamen (CN)

(72) Inventors: CHEN CHU, Xiamen (CN); JING CHEN, Xiamen (CN); ZHIKUN SHEN, Xiamen (CN); DEBING HUANG, Xiamen (CN); GUOHENG QIN, Xiamen (CN); JINGQIONG ZHANG, Xiamen (CN); CONGLIN WU, Xiamen (CN)

(21) Appl. No.: 19/236,003

(22) Filed: Jun. 12, 2025

(30) Foreign Application Priority Data
Jan. 14, 2025 (CN) 2025100584218

(51) Int. Cl. H10H 20/851; H10H 20/853

(52) U.S. Cl. CPC H10H 20/8514; H10H 20/8513; H10H 20/853

(57) ABSTRACT

A light-emitting device includes: a substrate; a light-emitting chip, disposed on the substrate; and a phosphor encapsulant covering the light-emitting chip. The phosphor encapsulant includes a narrowband phosphor. The phosphor encapsulant includes a first phosphor layer, covering an upper surface of the light-emitting chip, and a second phosphor layer, disposed on the first phosphor layer. In the light-emitting device, the first phosphor layer covers the upper surface of the light-emitting chip, the second phosphor layer covers the first phosphor layer, the first phosphor layer includes the narrowband phosphor and the silicone, and the narrowband phosphor is uniformly distributed within the silicone, so that the narrowband phosphor is close to the light-emitting chip, and the narrowband phosphor has high pureness in the silicone, which can improve an excitation efficiency of the narrowband phosphor, and improve heat dissipation efficiency.

### CROSS-REFERENCE TO RELATED APPLICATION

This application claims priority to Chinese Patent Application No. 202510058421.8, filed on January 14, 2025, which is herein incorporated by reference in its entirety.

### TECHNICAL FIELD

The disclosure relates to the field of lighting technologies, and more particularly to a light-emitting device and a preparation method thereof.

### BACKGROUND

Currently, light-emitting (LED) products incorporating fluoride-based phosphors are gaining increasing popularity due to their significantly higher spectral efficiency compared to conventional red phosphors such as nitrides. Fluoride phosphors including K₂SiF₆:Mn⁴⁺ (KSF), K₂TiF₆:Mn⁴⁺ (KTF), and K₂GeF₆:Mn⁴⁺ (KGF) are commonly referred to as narrowband red phosphors. These materials emit light in a red-light region of the visible spectrum upon excitation, with a peak emission wavelength (λpe) ranging from approximately 625 nm to 635 nm and a full width at half maximum (FWHM) of about 5 nm to 25 nm.

However, the excitation efficiency of fluoride phosphors under blue light is relatively low, and packages of white light LED products typically involves multiple phosphors (e.g., selected from garnets, silicates, scintillates, nitrides, fluorides and so on), which exhibit varying densities. When traditional processes—such as adhesive mixing, dispensing, and sedimentation—are employed, phosphors of various types are mixed and settle simultaneously. Phosphor with higher specific gravity sink faster and accumulate closer to a light-emitting surface of a chip. As a result, a proportion of the fluoride phosphor at a position close to the light-emitting surface of the chip is less than that of the fluoride phosphor at a position far away from the light-emitting surface of the chip. This uneven distribution further reduces the excitation and conversion efficiency of fluoride phosphors, ultimately degrading the overall luminous efficacy of white LED products.

### SUMMMARY

Therefore, in order to overcome at least some of defects and disadvantages in the related art, embodiments of the disclosure provide a light-emitting device and a preparation method thereof.

Specifically, in a first aspect, a light-emitting device according to an embodiment of the disclosure includes a substrate, a light-emitting chip and a phosphor encapsulant. The light-emitting chip is disposed on the substrate. The phosphor encapsulant covers the light-emitting chip, and the phosphor encapsulant includes a narrowband phosphor. The phosphor encapsulant includes a first phosphor layer and a second phosphor layer. The first phosphor layer covers an upper surface of the light-emitting chip, and the second phosphor layer is disposed on the first phosphor layer.

In another aspect, a preparation method of a light-emitting device according to an embodiment of the disclosure includes: disposing a light-emitting chip on a substrate; forming a first phosphor layer on an upper surface of the light-emitting chip by a powder spraying process or a dispensing process and using a first phosphor mixture, where the first phosphor mixture includes narrowband phosphor, silicone and a diluent; and forming a second phosphor layer on the first phosphor layer.

As can be seen from the above embodiments, in the light-emitting device provided by the embodiment of the disclosure, the first phosphor layer is disposed on the upper surface of the light-emitting chip, the second phosphor layer is disposed on the first phosphor layer, the first phosphor layer includes the narrowband phosphor and the silicone, and the narrowband phosphor is uniformly distributed within the silicone, so that the narrowband phosphor is close to the light-emitting chip, and the narrowband phosphor has a high pureness in the silicone, which can improve an excitation efficiency of the narrowband phosphor, and improve heat dissipation efficiency.

### BRIEF DESCRIPTION OF DRAWINGS

In order to describe technical solutions of embodiments of the disclosure more clearly, drawings required to be used in the descriptions of the embodiments are briefly introduced below. Apparently, the drawings in the following descriptions are merely some of embodiments of the disclosure, for those skilled in the art, other drawings can be obtained according to these drawings without creative work.

FIG. 1 illustrates a flowchart of a preparation method of a light-emitting device according to an embodiment of the disclosure.

FIG. 2 illustrates a schematic structural diagram of a light-emitting device according to an embodiment of the disclosure.

FIG. 3 illustrates a schematic structural diagram of a light-emitting device according to another embodiment of the disclosure.

FIG. 4 illustrates a schematic structural diagram of a light-emitting device according to still another embodiment of the disclosure.

FIG. 5 illustrates a schematic structural diagram of a light-emitting device according to even still another embodiment of the disclosure.

FIG. 6 illustrates a schematic structural diagram of a light-emitting device according to further still another embodiment of the disclosure.

FIG. 7 illustrates a schematic structural diagram of a light-emitting device according to even further still another embodiment of the disclosure.

### Description of reference signs

10-light-emitting device; 11-main light-emitting area; 12-peripheral area; 100-substrate; 200-light-emitting chip; 300-first phosphor layer; 400-second phosphor layer; 410-sedimentation layer; 420-clear encapsulation layer.

### DETAILED DESCRIPTION OF EMBODIMENTS

In order to clarify purposes, technical solutions, and advantages of embodiments of the disclosure, the technical solutions in the embodiments of the disclosure will be described clearly and completely below in conjunction with the drawings. Apparently, the described embodiments are merely some of embodiments of the disclosure, rather than all of embodiments of the disclosure. Based on the embodiments described in the disclosure, all other embodiments obtained by those skilled in the art without creative work are within a scope of protection of the disclosure.

It should be noted that all directional indications (such as up, down, left, right, front, back, top and bottom) in the embodiments of the disclosures are only used to explain the relative positional relationship and motion between the components in a specific posture (as shown in the drawings). When the specific posture changes, the directional indications will also change accordingly.

In the embodiments of the disclosure, descriptions related to “first” and “second” are only for descriptive purposes and cannot be understood as indicating or implying their relative importances or implying the number of technical features indicated. Therefore, the features that are limited with “first” and “second” can explicitly or implicitly include at least one of these features.

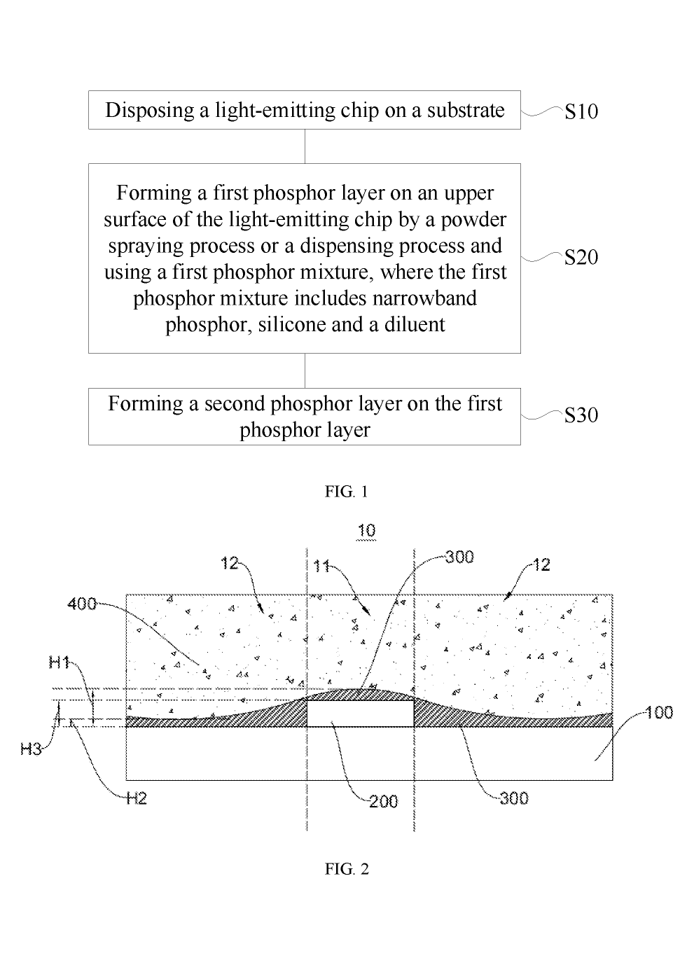

As shown in FIG. 1 and FIG. 2, embodiments of the disclosure provide a light-emitting device 10 and a preparation method of a light-emitting device, and the light-emitting device 10 shown in FIG. 2 can be prepared by the preparation method of the light-emitting device shown in FIG. 1.

As shown in FIG. 1, the preparation method of the light-emitting device 10 can include the following steps S10-S30.

In S10, a light-emitting chip is disposed on a substrate.

In S20, a first phosphor layer is formed on an upper surface of the light-emitting chip by a powder spraying process or a dispensing process and using a first phosphor mixture. The first phosphor mixture includes fluoride phosphor (i.e., narrowband phosphor), silicone and a diluent.

In S30, a second phosphor layer is formed on the first phosphor layer.

Specifically, a substrate 100 is provided, an upper surface of the substrate 100 can include a die bonding area, and a light-emitting chip 200 is fixed on the die bonding area on the substrate 100. In the embodiment, the light-emitting device 10 may be a surface mounted device (SMD) package, a chip on board (COP) package, or a filament package. The light-emitting chip 200 may be one or more. The preparation method of the embodiment has significant advantages in light-emitting devices 10 such as COB package and filament package with multiple (usually three or more) light-emitting chips 200 simultaneously on the substrate 100. A first phosphor layer 300 is formed on an upper surface (i.e., main light-emitting surface) of the light-emitting chip 200, which may include the following steps. The fluoride phosphor, the silicone and the diluent are mixed to form the first phosphor mixture, and the diluent may be siloxane or toluene. The first phosphor mixture is coated on the upper surface of the light-emitting chip 200 by the powder spraying process or the dispensing process. Due to volatilization characteristics of the diluent, the diluent volatilizes to form the first phosphor layer 300 including the fluoride phosphor and the silicone.

By adding the diluent in the mixture of the fluoride phosphor and the silicone, viscosity of the first phosphor mixture can be reduced, which can ensure that the first phosphor mixture can achieve a more rapid and uniform formation on the main light-emitting surface of the light-emitting chip 200 by the powder spraying process, or a uniform formation on the main light-emitting surface of the light-emitting chip 200 by a rapid leveling method of the dispensing process, thereby reducing the amount of the silicone. Moreover, the fluoride phosphor is uniformly distributed within the silicone, thereby improving an excitation conversion effect of the fluoride phosphor, and improving a luminous efficiency of the light-emitting device 10. In the embodiment, the first phosphor layer 300 can be only formed on the main light-emitting surface (i.e., the upper surface) of the light-emitting chip 200, or synchronously formed on the substrate 100 around the light-emitting chip 200 and/or coated on a side of the light-emitting chip 200. Specific embodiments will be described in the following in different implementations.

A second phosphor layer 400 is formed on the first phosphor layer 300, for example, by a method similar to the formation of the first phosphor layer 300 described above, or by a traditional dispensing process. Specifically, in an implementation of the embodiment, for example, other phosphors such as yellow-green phosphor and nitride red phosphor, the silicone and the diluent are mixed to form a second phosphor mixture, the second phosphor mixture is applied on the first phosphor layer 300 by the powder spraying process or the dispensing process. After the diluent volatilizes, the second phosphor layer 400 is formed. In another implementation of the embodiment, for example, the other phosphors such as the yellow-green phosphor and the nitride red phosphor, and the silicone are mixed to form a third phosphor mixture, and the third phosphor mixture is applied on the first phosphor layer 300 to form the second phosphor layer 400 by the traditional dispensing process. Certainly, the embodiment is not limited by this.

As shown in FIG. 2, the light-emitting device 10 provided by the embodiment of the disclosure may include a substrate 100, a light-emitting chip 200 and a phosphor encapsulant. The substrate 100 may be a metal substrate, a ceramic substrate, a glass substrate and a composite substrate. The light-emitting chip 200 may be a blue light-emitting chip, and the light-emitting chip 200 is disposed on the substrate 100. The phosphor encapsulant covers the light-emitting chip, and includes a narrowband phosphor. The phosphor encapsulant include a first phosphor layer 300 and a second phosphor layer 400. The first phosphor layer 300 is disposed on the light-emitting chip 200, the first phosphor layer 300 includes fluoride phosphor (i.e., narrowband phosphor) and silicone, and the fluoride phosphor is uniformly distributed within the silicone. The fluoride phosphor is manganese-activated fluoride red phosphor, and the commonly used fluoride phosphor includes K₂SiF₆:Mn⁴⁺ (KSF), K₂TiF₆:Mn⁴⁺ (KTF) and K₂GeF₆:Mn⁴⁺ (KGF). In an embodiment, the narrowband phosphor emits light in a red-light region of a visible spectrum upon excitation (e.g., excited by blue light emitted form a blue LED chip), with a peak emission wavelength (λpe) ranging from 625 nm to 635 nm and a FWHM ranging from 5 nm to 25 nm. The second phosphor layer 400 is disposed on the first phosphor layer 300, and the second phosphor layer 400 may include other phosphors such as the yellow-green phosphor and the nitride red phosphor (i.e., the second phosphor layer 400 includes phosphor having a color different from that of the first phosphor layer 300). Specifically, the first phosphor layer 300 includes a red phosphor, and the second phosphor layer 400 includes a yellow-green phosphor. In the light-emitting device 10 provided by the embodiment of the disclosure, the first phosphor layer 300 is disposed on the light-emitting chip 200, the second phosphor layer 400 is disposed on the first phosphor layer 300, and the first phosphor layer 300 includes the fluoride phosphor and the silicone. By sequentially layering the first phosphor layer 300 including the fluoride phosphor and the second phosphor layer 400 including the other phosphors on the light-emitting chip 200, the fluoride phosphor with low excitation efficiency is closer to the light-emitting chip 200, and especially closer to the main light-emitting surface of the light-emitting chip 200, which improve the excitation effect of the fluoride phosphor, thereby improving the luminous efficiency of the light-emitting device 10.

In an embodiment, the first phosphor layer 300 of the disclosure is formed on the light-emitting chip 200 by mixing the fluoride phosphor, the silicone and the diluent and using the powder spraying process or the dispensing process as shown in FIG. 1. The first phosphor layer 300 formed after the diluent volatilizes by this method exhibits specific structural characteristics, so that the first phosphor layer 300 can cover the main light-emitting surface of the light-emitting chip 200 conveniently and uniformly, which can achieve better excitation conversion effect and luminous efficiency by less amount of the phosphor. Specifically, as shown in FIG. 2, a space directly above the upper surface of the light-emitting chip 200 is defined as a main light-emitting area 11 (corresponding to the die bonding area where the light-emitting chip 200 is located), and an area other than the main light-emitting area 11 of the light-emitting chip 200 is defined as a peripheral area 12 (e.g., around the main light-emitting area 11), so that the first phosphor layer 300 covers the main light-emitting area 11 and the peripheral area 12. In an implementation of the embodiment, the first phosphor layer 300 may cover the upper surface and a side surface of the light-emitting chip 200, and cover an upper surface of the substrate 100. In some embodiments, the upper surface of the substrate 100 is taken as a reference surface, a height H1 of an upper surface of the first phosphor layer 300 in the main light-emitting area 11 is greater than a height H2 of an upper surface of the first phosphor layer 300 in the peripheral area 12, that is, the height H1 between the upper surface of the first phosphor layer 300 in the main light-emitting area 11 and the upper surface of the substrate 100 is greater than the height H2 between the upper surface of the first phosphor layer 300 in the peripheral area 12 and the upper surface of the substrate 100. In other words, the first phosphor layer 300 will exhibit undulations in height in a cross-sectional view of the light-emitting device 10 perpendicular to the upper surface of the light-emitting chip 200. In some embodiments, the height H2 of the upper surface of the first phosphor layer 300 in the peripheral area 12 is even lower than a height H3 of the upper surface of the light-emitting chip 200, that is, a height between the upper surface of the first phosphor layer 300 in the peripheral area 12 and the upper surface of the substrate 100 is lower than a height between the upper surface of the light-emitting chip 200 and the upper surface of the substrate 100. From another perspective, in the embodiment, the second phosphor layer 400 is formed on the first phosphor layer 300, and will also be simultaneously formed in the main light-emitting area 11 and the peripheral area 12. A height of a lower surface of the second phosphor layer 400 in the peripheral area 12 is lower than a height of a lower surface of the second phosphor layer 400 in the main light-emitting area 11. In some embodiments, the height of the lower surface of the second phosphor layer 400 in the peripheral area 12 is even lower than the height H3 of the upper surface of the light-emitting chip 200.

In the embodiments of the disclosure, a package form of the light-emitting device 10 is a COB package, a SMD package or a filament package. It is particularly worth mentioning that, for the light-emitting device 10 with the COV package or other multi-chip (over three) packages (i.e., with a large package area), using the first phosphor layer 300 formed on the light-emitting chip 200 by mixing the fluoride phosphor, the silicone and the diluent and using the powder spraying process or the dispensing process in the disclosure, overcomes the problem of traditional layered dispensing technology being difficult to implement in larger packaging areas, and achieves the effect of fluoride phosphor covering the main light-emitting surface of the light-emitting chip 200 more conveniently and uniformly, thereby improving the luminous efficiency and uniformity of such products.

In addition, in the first phosphor layer 300 of the light-emitting device 10 provided by some embodiments of the disclosure, the fluoride phosphor is distributed uniformly and not layered. In addition, a mass percentage (i.e., a ratio of a mass of the fluoride phosphor to a total mass of the fluoride phosphor and the silicone in the first phosphor layer 300) can achieve over 60%, even over 70%; while in the traditional dispensing process, when the mass percentage of the fluoride phosphor is over 50%, there is a problem of poor fluidity and difficulty in evenly dispensing. Therefore, the disclosure can reduce the amount of fluoride phosphor used while achieving high excitation conversion effect and high luminous efficiency. By such settings, it can avoid the impact of high silicone content in the first phosphor layer 300 on the heat dissipation of the light-emitting device 10. However, it should be noted that the mass percentage of the fluoride phosphor in the first phosphor layer 300 of the light-emitting device 10 of the disclosure can achieve over 60%, and is not limited to over 60% in all embodiments. The specific selection will be adjusted according to the light-emitting requirements of the light-emitting device 10 and other phosphor used.

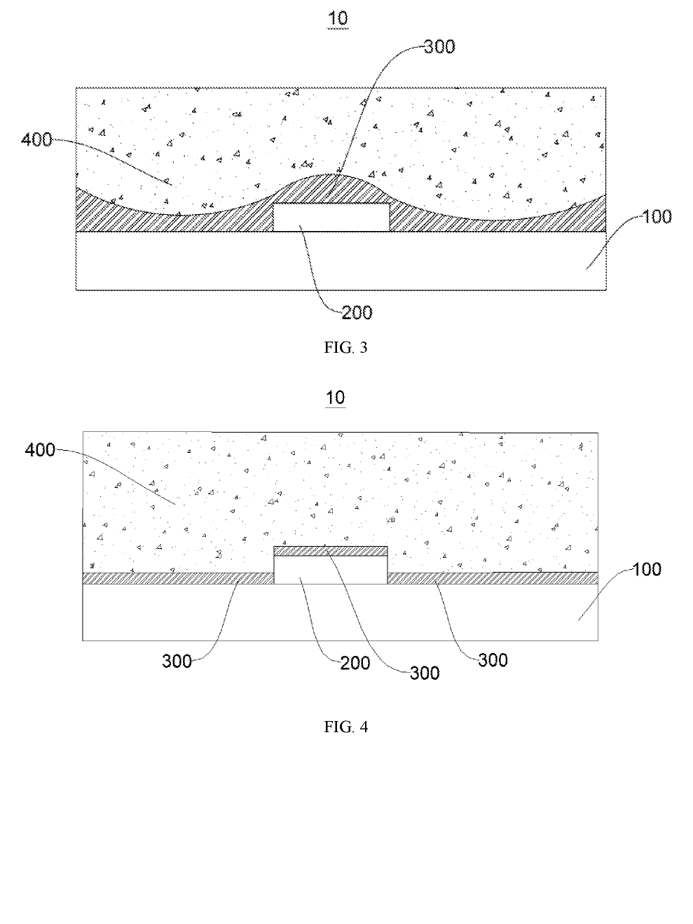

In the embodiments of the disclosure, a mass ratio between the fluoride phosphor and the silicone in the first phosphor layer 300 is in a range of 1: 9 to 9: 1, that is, the mass percentage of the fluoride phosphor in the first phosphor layer 300 is in a range of 10% to 90%. In an embodiment, the mass percentage of the fluoride phosphor in the first phosphor layer 300 is in a range of 60% to 90%. By such setting, it can avoid the impact of high silicone content in the first phosphor layer 300 on the heat dissipation. In some embodiments of the disclosure, as shown in FIG. 3, when the usage amount of the first phosphor layer 300 is large, or the mass ratio between the fluoride phosphor and the silicone is low, the upper surface of the first phosphor layer 300 will be a relatively smooth curved surface, which has a small height difference. As shown in FIG. 2, when the usage amount of the first phosphor layer 300 is small, or the mass ratio between the fluoride phosphor and the silicone is large, the upper surface of the first phosphor layer 300 will have a larger height difference. As shown in FIG. 4, when the usage amount of the first phosphor layer 300 is small, or the mass ratio between the fluoride phosphor and the silicone is large, the upper surface of the first phosphor layer 300 is even broken, resulting in discontinuity of the upper surface of the first phosphor layer 300. The aforementioned different structures of the first phosphor layer 300 belong to the specific structural features presented by the first phosphor layer 300 formed by the preparation method of the light-emitting device 10 provided in the embodiments of the disclosure, and are applicable to the corresponding different embodiments described below.

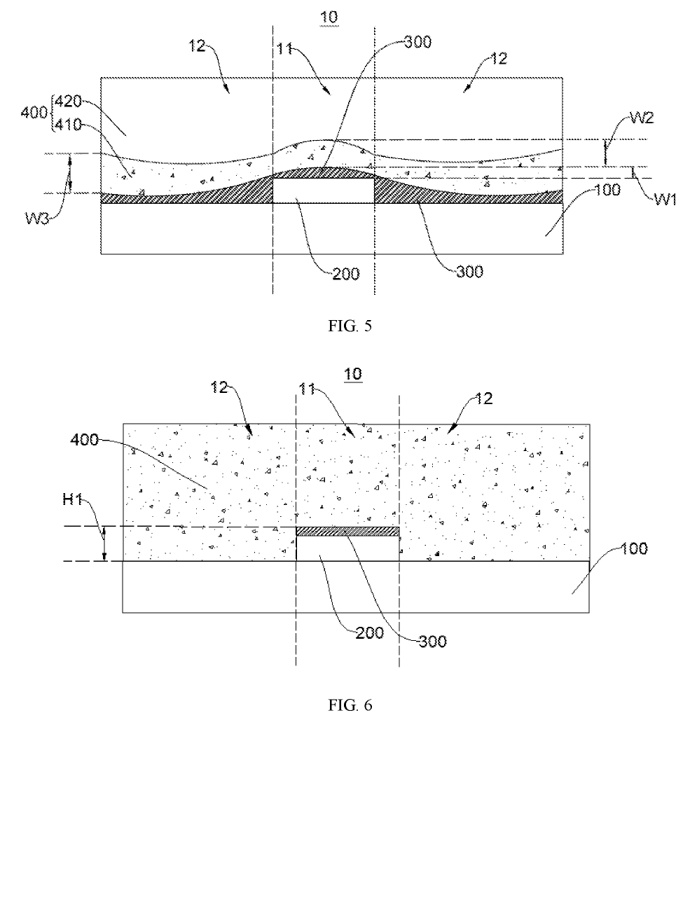

Referring to FIG. 5, FIG. 5 is another embodiment of the disclosure, and selections and settings of the substrate 100, the light-emitting chip 200 and the first phosphor layer 300 included by the light-emitting device 10 provided by the embodiment are the same as the embodiment shown in FIG. 2, which won't be repeated here. The main difference between the embodiment and the embodiment shown in FIG. 2 is that the second phosphor layer 400 provided in the embodiment is layered on the first phosphor layer 300. In terms of the preparation method, natural sedimentation and centrifugal/semi centrifugal sedimentation steps can be added on the basis of the aforementioned method of forming the second phosphor layer 400, so that almost other phosphors in the second phosphor layer 400 in the embodiment deposit onto the surface of the first phosphor layer 300, thereby causing the second phosphor layer 400 to exhibit a layered structure. That is, the second phosphor layer 400 may include a sedimentation layer 410 close to the first phosphor layer 300 and a clear encapsulation layer 420 located on a side of the sedimentation layer 410 opposite to the first phosphor layer 300. That is, the clear encapsulation layer 420 is located on a side of the sedimentation layer 410 opposite to the first phosphor layer 300 and opposite to the light-emitting chip 200. It should be noted that, the clear encapsulation layer 420 is not completely free of phosphor, but the content/concentration of phosphor visible to naked eyes in the clear encapsulation layer 420 is lower than that in the sedimentation layer 410.

On the other hand, in a cross-sectional view of the light-emitting device 10 perpendicular to the main light-emitting surface of the light-emitting chip 200 in the embodiment, the phosphor may be displayed as a three-layer structure, including the first phosphor layer 300, the sedimentation layer 410 and the clear encapsulation layer 420. The sedimentation layer 410 is located between the first phosphor layer 300 and the clear encapsulation layer 420, and the clear encapsulation layer 420 is located on a side of the sedimentation layer 410 opposite to the light-emitting chip 200. The second phosphor layer 400 is formed on the first phosphor layer 300, and will also be simultaneously formed in the main light-emitting area 11 and the peripheral area 12. The height of the lower surface of the second phosphor layer 400 in the peripheral area 12 is lower than the height of the lower surface of the second phosphor layer 400 in the main light-emitting area 11, that is, a height between a lower surface of the second phosphor layer 400 in the peripheral area 12 and the upper surface of the substrate 100 is less than a height between a lower surface of the second phosphor layer 400 in the main light-emitting area 11 and the upper surface of the substrate 100, so that the phosphor in the second phosphor layer 400 can be more concentrated close to the substrate 100, which helps to dissipate the heat of the phosphor in the second phosphor layer 400 downwards by the substrate 100, thereby improving the thermal stability of the light-emitting device 10. In some implementations of the embodiment, in order to ensure a better heat dissipation effect, the sedimentation step is added when forming the second phosphor layer 400, so that the second phosphor layer 400 flows better and the phosphor contained therein tends to precipitate towards a direction of the substrate 100. The height difference of the first phosphor layer 300 between the main light-emitting area 11 and the peripheral area 12 is also filled, so that an interface between the first phosphor layer 300 and the sedimentation layer 410 presents a relatively larger height difference, while an interface between the sedimentation layer 410 and the clear encapsulation layer 420 presents a smaller height difference. In the other hand, a thickness W3 of the sedimentation layer 410 of the second phosphor layer 400 in the peripheral area 12 is greater than a thickness W2 of the sedimentation layer 410 in the main light-emitting area 11. For the color rendering index (CRI) 90 series light-emitting device 10, it is necessary to allocate appropriate a proportion of the fluoride phosphor with the other phosphors to ensure the light-emitting effect (light color and CRI). It is necessary to control the amount of the first phosphor layer 300 to ensure better thermal stability (e.g., improving the heat dissipation effect). Current experiments have found that when a ratio of the thickness W1 of the first phosphor layer 300 located in the main light-emitting area 11 to the thickness W2 of the sedimentation layer 410 located in the main light-emitting area 11 is less than 2, the aforementioned good effect can be uniformly achieved. In an embodiment, the thickness W1 of the first phosphor layer 300 located in the main light-emitting area 11 is less than the thickness W2 of the sedimentation layer 410 located in the main light-emitting area 11.

Referring to FIG. 6, FIG. 6 is another embodiment of the disclosure, and selections and settings of the substrate 100, the light-emitting chip 200 and the second phosphor layer 400 included by the light-emitting device 10 provided by the embodiment are the same as the embodiment shown in FIG. 2, which won't be repeated here. The main difference between the embodiment and the embodiment shown in FIG. 2 is that the first phosphor layer 300 only covers the main light-emitting surface 11, and is not disposed in the peripheral area 12, when the second phosphor layer 400 is formed on the first phosphor layer 300, the second phosphor layer 400 will be located on a side of the first phosphor layer 300 facing away from the light-emitting chip 200 in the main light-emitting area 11, and will be directly located on the substrate 100 in the peripheral area 12. However, in this case, it is also consistent that the height H1 of the upper surface of the first phosphor layer 300 in the main light-emitting area 11 is greater than the height H2 of the upper surface of the first phosphor layer 300 in the peripheral area 12 (in the embodiment, this thickness is equal to 0); or more precisely, the height of the lower surface of the second phosphor layer 400 in the peripheral area 12 will be lower than the height of the lower surface of the second phosphor layer 400 in the main light-emitting area 11.

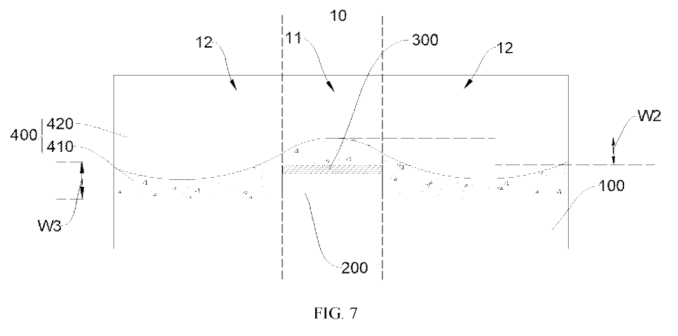

Referring to FIG. 7, FIG. 7 is another embodiment of the disclosure, and selections and settings of the substrate 100, the light-emitting chip 200 and the first phosphor layer 300 included by the light-emitting device 10 provided by the embodiment are the same as the embodiment shown in FIG. 6, which won't be repeated here. The main difference between the embodiment and the embodiment shown in FIG. 6 is that the second phosphor layer 400 provided in the embodiment is layered on the first phosphor layer 300. In terms of the preparation method, natural sedimentation and centrifugal/semi centrifugal sedimentation steps can be added on the basis of the aforementioned method of forming the second phosphor layer 400, so that almost other phosphors in the second phosphor layer 400 in the embodiment deposit onto the surface of the first phosphor layer 300, thereby causing the second phosphor layer 400 to exhibit a layered structure. That is, the second phosphor layer 400 may include a sedimentation layer and a clear encapsulation layer 420 located on the sedimentation layer 410. The main difference of the second phosphor layer 400 between the embodiment and the embodiment shown in FIG. 5 is that in the peripheral area 12, the sedimentation layer 410 is disposed on the substrate 100. However, the height of the lower surface of the second phosphor layer 400 in the peripheral area 12 will be lower than the height of the lower surface of the second phosphor layer 400 in the main light-emitting area 11, the thickness W3 of the sedimentation layer 410 of the second phosphor layer 400 in the peripheral area 12 is greater than the thickness W2 of the sedimentation layer 410 in the main light-emitting area 11, so that the phosphor in the second phosphor layer 400 can be more concentrated close to the substrate 100, which helps to dissipate the heat of the phosphor in the second phosphor layer 400 downwards by the substrate 100, thereby improving the thermal stability of the light-emitting device 10.

Furthermore, it can be understood that the aforementioned embodiments are merely illustrative of the disclosure, and the technical solutions of each embodiment can be arbitrarily combined and used in combination, provided that the technical features do not conflict, the structure does not conflict, and the disclosure objectives do not violate the disclosure.

Finally, it should be noted that the above embodiments are merely used to illustrate the technical solution of the disclosure, and not to limit it. Although the disclosure has been described in detail with reference to the aforementioned embodiments, those skilled in the art should understand that they can still modify the technical solutions described in the aforementioned embodiments, or equivalently replace some of the technical features. These modifications or substitutions do not depart from the essence and scope of the corresponding technical solutions of the embodiments of the disclosure.

What is claimed is:

1. A light-emitting device, comprising:
a substrate;
a light-emitting chip disposed on the substrate; and
a phosphor encapsulant covering the light-emitting chip; wherein the phosphor encapsulant comprises a narrowband phosphor; and the phosphor encapsulant comprises:
a first phosphor layer, covering an upper surface of the light-emitting chip; and
a second phosphor layer, disposed on the first phosphor layer.

2. The light-emitting device as claimed in claim 1, wherein the first phosphor layer is directly arranged on the upper surface of the light-emitting chip, and the second phosphor layer covers an upper surface of the first phosphor layer and at least a portion of an upper surface of the substrate.

3. The light-emitting device as claimed in claim 1, wherein the first phosphor layer covers the upper surface of the light-emitting chip, at least a portion of an upper surface of the substrate and at least a portion of a side surface of the light-emitting chip, and the second phosphor layer covers the first phosphor layer.

4. The light-emitting device as claimed in claim 1, wherein the first phosphor layer covers the upper surface of the light-emitting chip and at least a portion of an upper surface of the substrate, and the second phosphor layer covers the first phosphor layer and a side surface of the light-emitting chip.

5. The light-emitting device as claimed in claim 3, wherein a height between an upper surface of the first phosphor layer directly above the light-emitting chip and the upper surface of the substrate is greater than a height between an upper surface of the first phosphor layer directly above the substrate and the upper surface of the substrate.

6. The light-emitting device as claimed in claim 4, wherein a height between an upper surface of the first phosphor layer directly above the light-emitting chip and the upper surface of the substrate is greater than a height of an upper surface of the first phosphor layer directly above the substrate and the upper surface of the substrate.

7. The light-emitting device as claimed in claim 5, wherein the height between the upper surface of the first phosphor layer directly above the substrate and the upper surface of the substrate is less than a height between the upper surface of the light-emitting chip and the upper surface of the substrate.

8. The light-emitting device as claimed in claim 1, wherein the second phosphor layer comprises a sedimentation layer and a clear encapsulation layer, and the clear encapsulation layer is located on a side of the sedimentation layer opposite to the substrate.

9. The light-emitting device as claimed in claim 8, wherein a ratio of a thickness of the first phosphor layer directly on the upper surface of the light-emitting chip to a thickness of the sedimentation layer above the upper surface of the light-emitting chip is less than 2.

10. The light-emitting device as claimed in claim 9, wherein the thickness of the first phosphor layer directly on the upper surface of the light-emitting chip is less than the thickness of the sedimentation layer above the upper surface of the light-emitting chip.

11. The light-emitting device as claimed in claim 8, wherein a concentration of phosphor in the clear encapsulation layer is less than a concentration of phosphor in the sedimentation layer.

12. The light-emitting device as claimed in claim 1, wherein the first phosphor layer comprises the narrowband phosphor, the narrowband phosphor is uniformly distributed within silicone, and the narrowband phosphor is configured to emit light in a red-light region of a visible spectrum upon excitation, with a peak emission wavelength (λpe) ranging from 625 nanometers (nm) to 635 nm and a full width at half maximum (FWHM) ranging from 5 nm to 25 nm.

13. The light-emitting device as claimed in claim 12, wherein a mass ratio of the narrowband phosphor to the silicone in the first phosphor layer is in a range of 1: 9 to 9: 1; or a mass percentage of the narrowband phosphor in the first phosphor layer is in a range of 60%-90%.

14. A light-emitting device, comprising:
a substrate;
a light-emitting chip, disposed on the substrate;
a phosphor encapsulant covering the light-emitting chip; wherein the phosphor encapsulant comprises a narrowband phosphor; and the phosphor encapsulant comprises:
a first phosphor layer, directly disposed on the light-emitting chip; and
a second phosphor layer, disposed on the first phosphor layer, wherein the second phosphor layer comprises phosphor having a color different from that of the first phosphor layer.

15. The light-emitting device as claimed in claim 14, wherein the first phosphor layer comprises a red phosphor, and the second phosphor layer comprises a yellow-green phosphor.

16. The light-emitting device as claimed in claim 14, wherein an upper surface of the substrate has a die bonding area where the light-emitting chip is located; the second phosphor layer comprises a sedimentation layer and a clear encapsulation layer, and the clear encapsulation layer is located on a side of the sedimentation layer opposite to the substrate, a concentration of phosphor in the clear encapsulation layer is less than a concentration of phosphor in the sedimentation layer; and a ratio of a thickness of the first phosphor layer in the die bonding area to a thickness of the sedimentation layer in the die bonding area is less than 2.

17. The light-emitting device as claimed in claim 16, wherein the thickness of the first phosphor layer in the die bonding area is less than the thickness of the sedimentation layer in the die bonding area.

18. The light-emitting device as claimed in claim 14, wherein an upper surface of the first phosphor layer is an undulating surface in height, and a lower surface of the second phosphor layer is in contact with the upper surface of the first phosphor layer.

19. A light-emitting device, comprising:
a substrate;
a light-emitting chip, disposed on the substrate; and
a phosphor encapsulant covering the light-emitting chip; wherein the phosphor encapsulant comprises a narrowband phosphor; and the phosphor encapsulant comprises:
a first phosphor layer, covering an upper surface of the light-emitting chip and at least a portion of an upper surface of the substrate, wherein the first phosphor layer has an undulating upper surface in height; and
a second phosphor layer, disposed on the first phosphor layer.

20. The light-emitting device as claimed in claim 19, wherein the second phosphor layer comprising a sedimentation layer and a clear encapsulation layer, the sedimentation layer is located on a side of the first phosphor layer opposite to the substrate, and the clear encapsulation layer is located on a side of the sedimentation layer opposite to the first phosphor layer; and a concentration of phosphor in the clear encapsulation layer is less than a concentration of phosphor in the sedimentation layer.
